(19) United States
(12) Patent Application Publication
(10) Pub. No.: US 2016/0098068 A1
(43) Pub. Date: Apr. 7, 2016

(54) COMPUTER CASE PROVIDING MULTIPLE INDEPENDENT AIRFLOWS

(71) Applicant: ANTEC, INC., Taipei (TW)

(72) Inventor: Han Lung LIU, Fremont, CA (US)

(21) Appl. No.: 14/508,487

(22) Filed: Oct. 7, 2014

(51) Int. Cl. G06F 1/20; H05K 7/20

(52) U.S. Cl. CPC G06F 1/20; H05K 7/20145

(57) ABSTRACT

A computer case providing multiple independent airflows includes a case body which has an installation space. The installation space includes a logic process zone, a magnetic disk zone and a spaced zone. The case body also has a flow guide passage in the spaced zone to allow external air to enter the installation space, at least one first air fan located in the installation space to be electrically activated to provide a first airflow to the logic process zone and a second air fan located in the installation space at one side of the magnetic disk zone to be electrically activated to provide a second airflow to the magnetic disk zone. The invention, through the flow guide passage, can directly get the external air to perform cooling of the logic process zone and provide multiple airflows to cool electronic elements installed in the installation space.

### FIELD OF THE INVENTION

The present invention relates to a computer case and particularly to a computer case equipped with multiple independent airflow paths to facilitate cooling.

### BACKGROUND OF THE INVENTION

With growing process performance of computer elements, the electric power they consume also increases, that results in increasing of their operation temperature that could cause overheat and easily make the computer elements to suffer heat crash or damage. To address this concern nearly all consumer electronic product manufacturers have tried to provide solutions or improve structural design to attack the cooling problem of the computer elements. For instance, Taiwan Patent No. M253827 and Chinese patent publication No. 103135706 disclose a computer case with improved cooling. It is equipped with a cooling air fan. When the air fan is activated a cooling airflow is generated in an installation space inside the computer case to provide cooling for computer elements installed in the installation space. However, the cooling air fan equipped in the computer case generally is located at the substantial front end or rear end of the computer case to channel external air to form the cooling airflow.

Take the cooling air fan located at the eventual front end as an example. When the cooling air fan is activated, it draws the external air into the installation space to perform cooling first for the computer elements installed on the front end of the computer case, and the external air receives the thermal energy of the computer elements and has a higher temperature, then the partially heated air is moved by the cooling air fan to perform cooling for a motherboard located at the rear end of the computer case. The external air that is partially heated cannot provide heat exchange as effective as air of a lower temperature, hence the motherboard also cannot be cooled as effective as desired. While the aforesaid two techniques provide a design concept of installing the air fan in the middle, it substantially provides stronger cooling airflow in the computer case without drawing the external air into the installation space to provide the external air of a lower temperature to perform cooling for the motherboard. Thus waste heat accumulated on the motherboard still cannot be dispelled to make cooling as effective as desired.

### SUMMARY OF THE INVENTION

The primary object of the present invention is to solve the cooling problem of the conventional computer cases of relying single airflow that results in inferior cooling effect.

To achieve the foregoing object the present invention provides a computer case with multiple independent airflows. The computer case includes a case body which is hollow inside to form an installation space. The installation space includes a logic process zone, a magnetic disk zone abutting the logic process zone and a spaced zone located between the logic process zone and the magnetic disk zone. The case body also has a flow guide passage in the spaced zone to allow external air to enter the installation space. The flow guide passage has an open side at one side facing the logic process zone and a closed size at another side facing the magnetic disk zone. The computer case further has at least one first air fan and one second air fan. The first air fan is located on one side of the logic process zone. After being electrically activated the first air fan provides a first airflow to draw the external air from the flow guide passage to enter the logic process zone. The second air fan is located on one side of the magnetic disk zone After being electrically activated the second air fan provides a second airflow to the magnetic disk zone.

In one aspect the first airflow flows in a direction parallel with a logic process element located in the logic process zone.

In another aspect the first air fan is located on one side of the logic process zone facing the spaced zone.

In yet another aspect the first air fan is located on another side of the logic process zone remote from the spaced zone and on the top surface of the case body.

In yet another aspect the first air fan is located on another side of the logic process zone remote from the spaced zone.

In yet another aspect the case body has a first filter mesh located on one side of the logic process zone facing the spaced zone.

In yet another aspect the case body has a second air vent located on one side of the magnetic disk zone. The second air fan is located on another side of the magnetic disk zone opposing the second air vent.

In yet another aspect the installation space has a power supply zone located in the logic process zone without connecting to the spaced zone. The computer case further has a fourth air fan collaborated with the first air fan to provide a third airflow to the power supply zone.

In yet another aspect the fourth air fan is a power supply air fan and the third airflow flows in a direction parallel with the first airflow.

In yet another aspect the case body has a line passing channel located in the spaced zone and communicated with the logic process zone and the power supply zone to hold an electric line.

In yet another aspect the line passing channel is located in the spaced zone between the substantial top end and the substantial bottom end of the case body.

In addition to the structure set forth above, the invention also provides another embodiment in which the computer case has a case body hollow inside to form an installation space. The installation space includes a logic process zone, a magnetic disk zone abutting the logic process zone and a spaced zone located between the logic process zone and the magnetic disk zone. The case body also has a flow guide passage located in the spaced zone to allow external air to enter the installation space. The computer case further has at least one first air fan and one second air fan. The first air fan is located in the installation space on one side of the logic process zone abutting the spaced zone. After being electrically activated the first air fan provides a first airflow to the logic process zone. The first airflow has a first air intake end to draw the external air from the flow guide passage and a first air discharge end at one side of the logic process zone remote from the spaced zone to allow the external air to flow out from the installation space. The second air fan is located in the installation space on one side of the magnetic disk zone. After being electrically activated the second air fan provides a second airflow to the magnetic disk zone. The second airflow does not interfere with the first airflow, and has a second air intake end and a second air discharge end located respectively at two sides of the magnetic disk zone.

In one aspect the first airflow flows in a direction parallel with a logic process element located in the logic process zone.

In another aspect the computer case further includes a third air fan located in the installation space at the first air discharge end of the first airflow.

In yet another aspect the case body further has a first air vent located on one side of the logic process zone remote from the spaced zone and at the first air discharge end of the first airflow.

In yet another aspect the case body further includes a first detent wall located at one side of the magnetic disk zone abutting the spaced zone to confine the second airflow, and a second air vent located in the magnetic disk zone at two sides where the first detent wall is not located and opposing the second air fan to allow the external air to flow through.

In yet another aspect the second air intake end of the second airflow is located on the second air vent, and the second air discharge end is located on the second air fan.

In yet another aspect the second air fan is located on a substantial upper end of the magnetic disk zone, and the second air vent is located on a substantial lower end of the magnetic disk zone.

In yet another aspect the second air fan is located on one side of the magnetic disk zone abutting the spaced zone to form the second air intake end of the second airflow, the case body has the second air vent on one side of the magnetic disk zone without the second air fan installed thereon to form the second air discharge end of the second airflow.

In yet another aspect the case body has a second filter mesh located at one side of the magnetic disk zone abutting the spaced zone to confine external dust at the second air intake end of the second airflow.

In yet another aspect the computer case includes two side boards at two sides of the case body to seal the installation space after installation. Each side board has a flow vent cluster corresponding to the spaced zone and communicating with the installation space to form the flow guide passage.

In yet another aspect the computer case includes two side boards at two sides of the case body to seal the installation space after installation. Each side board has a plurality of flow vent clusters corresponding to the spaced zone. The flow vent clusters are spaced from each other at a preset interval and communicated with the installation space to form the flow guide passage.

In yet another aspect the case body has a longitudinal flow guide channel corresponding to the spaced zone and communicating with the installation space to form the flow guide passage.

In yet another aspect the case body has a first filter mesh located at one side of the logic process zone abutting the spaced zone to confine external dust at the first air intake end of the first airflow.

In yet another aspect the installation space has a power supply zone at one side of the logic process zone not connecting to the spaced zone, and the computer case further has a fourth air fan to receive electric power and supply a third airflow to the power supply zone.

In yet another aspect the fourth air fan is a power supply air fan.

In yet another aspect the case body has a second detent wall located between the logic process zone and the power supply zone to confine the first airflow and the third airflow.

In yet another aspect the computer case has a top air fan located on the substantial top end of the logic process zone to be activated electrically to provide a fourth airflow to the logic process zone.

In yet another aspect the fourth airflow directs the external air outside from the installation space.

In yet another aspect the case body has a line passing channel located in the spaced zone and communicated with the logic process zone and the power supply zone to hold an electric line.

In yet another aspect the line passing channel is located in the spaced zone between the substantial top end and the substantial bottom end of the case body.

Through the aforesaid structure, compared with the conventional techniques, the invention provides many advantageous features, notably:

1. By providing multiple airflows that do not interfere with each other to perform cooling respectively for the logic process zone and the magnetic disk zone, each airflow can draw the external air outside the case body inward to perform cooling, hence the unheated external air can be used to perform cooling for the logic process zone and the magnetic disk zone.

2. The flow guide passage can draw the external air to form the first airflow to directly perform cooling for the logic process zone, therefore logic process elements located in the logic process zone can get improved cooling effect.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a perspective view of the invention.

FIG. 2 is a fragmentary exploded view of a first embodiment of the case body of the invention.

FIG. 3 is an internal side view of the first embodiment of the case body of the invention.

FIG. 4 is a fragmentary exploded view of a second embodiment of the case body of the invention.

FIG. 5 is an internal side view of the second embodiment of the case body of the invention.

FIG. 6 is a schematic view of airflow paths of the second embodiment of the case body of the invention.

FIG. 7 is a side view of a third embodiment of the case body of the invention.

FIG. 8 is a side view of a fourth embodiment of the case body of the invention.

FIG. 9 is an internal side view of a fifth embodiment of the case body of the invention.

FIG. 10 is an internal side view of a sixth embodiment of the case body of the invention.

FIG. 11 is an internal side view of the seventh embodiment of the case body of the invention.

### DETAILED DESCRIPTION OF THE PREFERRED EMBODIMENTS

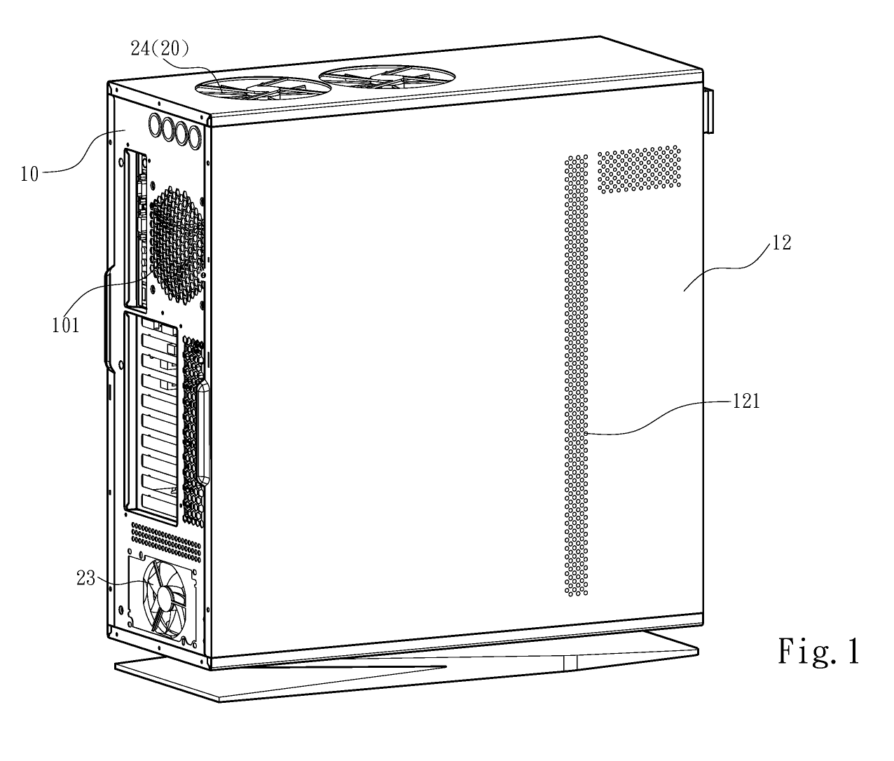

Please referring to FIG. 1, the present invention aims to provide a computer case with multiple independent airflows. The computer case mainly includes a case body 10 which can be fabricated mechanically through a plurality of metal plates or plastic sheets. The case body 10 is hollow inside to form an installation space 11 and has two side boards 12 located at two sides to seal the installation space 11 after installation. More specifically, the installation space 11 includes a logic process zone 111, a magnetic disk zone 112 abutting the logic process zone 111 and a spaced zone 113 located between the logic process zone 111 and the magnetic disk zone 112. The logic process zone 111 includes at least one logic process element 13 inside that can be a central processor or a display card. The magnetic disk zone 112 houses at least one hard disk 14 inside. The case body 10 further has a flow guide passage 15 located in the spaced zone 113 to allow external air to enter the installation space 11.

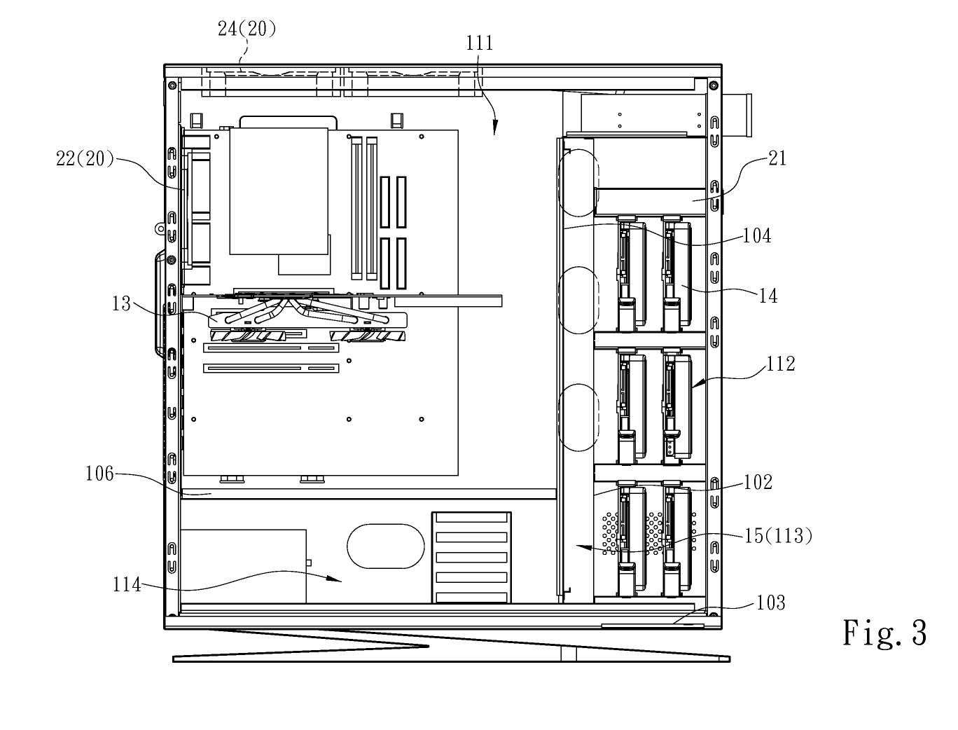

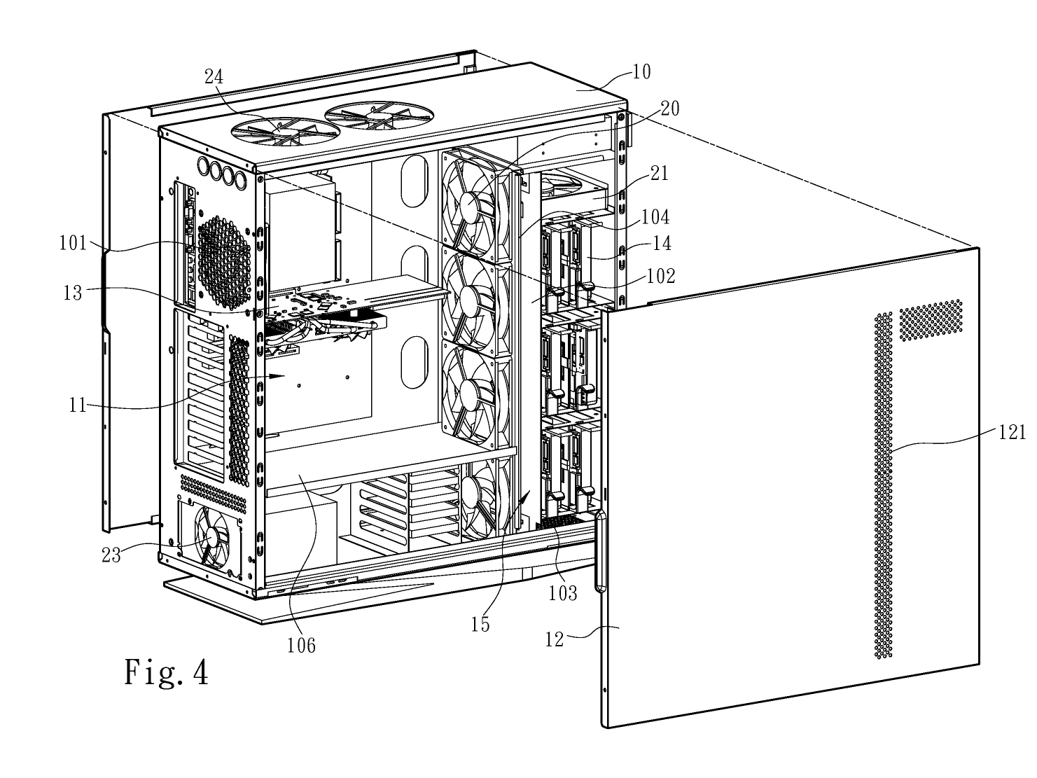

Please referring to FIGS. 1 through 4, in an embodiment the flow guide passage 15 has an open side at one side to face the logic process zone 111 and a closed side at another side to face the magnetic disk zone 112. More specifically, the open side means that the flow guide passage 15 is communicating with the logic process zone 111, while the closed side means that the flow guide passage 15 and the magnetic disk zone 112 do not communicate with each other directly, and are interposed by at least one detent wall between them. In this embodiment the computer case includes at least one first air fan 20 and at least one second air fan 21. The first air fan 20 is located at one side of the logic process zone 111, such as one side thereof facing the flow guide passage 15, or another side remote from the spaced zone 113 at the top of the case body 10, or yet another side remote from the spaced zone 113. The first air fan 20 receives electric power and provides a first airflow 201 to draw the external air from the flow guide passage 15 to enter the logic process zone 111. The first airflow 201 draws the external air through the open side of the flow guide passage 15 to enter the logic process zone 111 to perform heat exchange with the logic process element 13, then is discharged outside the case body 10, thereby form a cycle to perform cooling to the logic process zone 111.

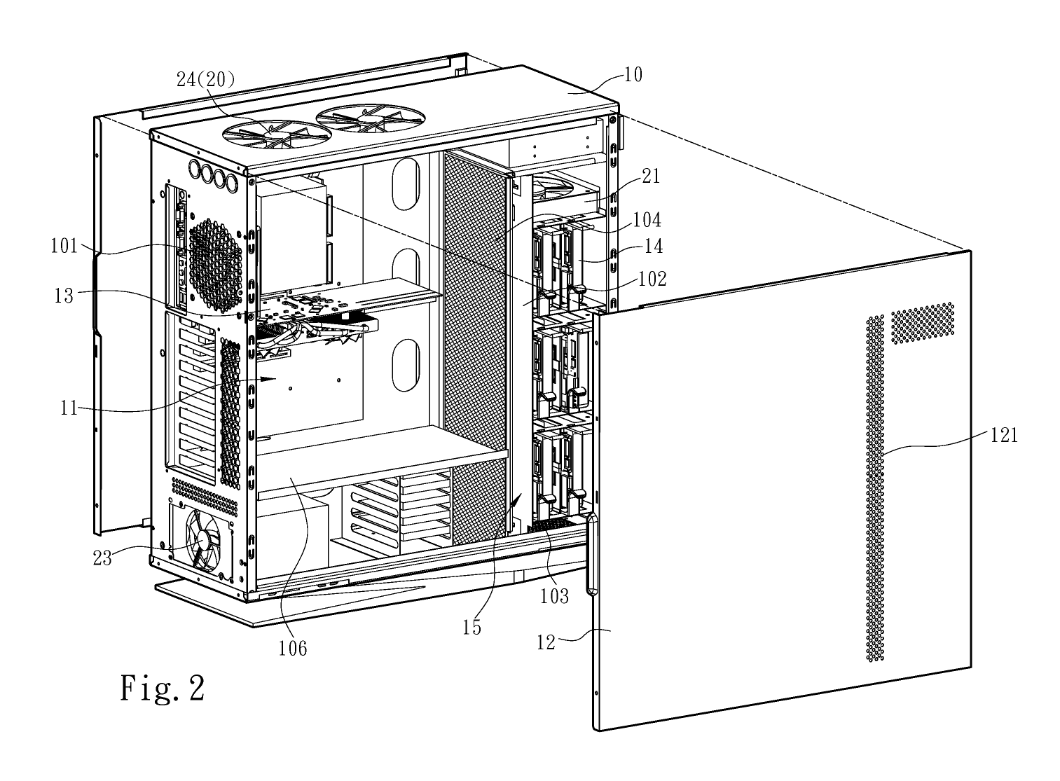

Also referring to FIGS. 1 and 2, in one embodiment the case body 10 further has a first filter mesh 104 located at one side of the logic process zone 111 facing the spaced zone 113. The first filter mesh 104 confines dust carried by the external air to prevent a great amount of them from entering the logic process zone 111 and the communicated flow guide passage 15 so that operation of the logic process element 13 is not affected. Moreover, the second air fan 21 is located at one side of the magnetic disk zone 112. The second air fan 21 is activated electrically to provide a second airflow 211 to the magnetic disk zone 112. More specifically, the case body 10 can have a second air vent 103 at one side where the magnetic disk zone 112 is located, and the second air fan 21 is located at another side of the magnetic disk zone 112 opposing the second air vent 103. For instance, the second air vent 103 can be located on the substantial bottom side of the case body 10, while the second air fan 21 can be located at the substantial top side of the case body 10. Thus, the second airflow 211 flows in a direction perpendicular to the flow direction of the first air flow 201.

Furthermore, in another embodiment the computer case has at least one air fan 20 and one second air fan 21 at the same time. The first air fan 20 is located in the installation space 11 at one side of the logic process zone 111 abutting the spaced zone 113, and is set to be electrically activated to draw the external air from the flow guide passage 15 into the installation space 11 to provide the first airflow 201 to perform cooling of the logic process zone 111. The first airflow 201 flows in a direction parallel with the logic process element 13 located in the logic process zone 111. The first airflow 201 also has a first air intake end to draw the external air from the flow guide passage 15 and a first air discharge end at one side of the logic process zone 111 remote from the spaced zone 113 to discharge the external air outside the installation space 11. More specifically, the first airflow 201 draws the external air into the case body 10 through the first air intake end, and the external air flows toward the logic process zone 111 to perform heat exchange with the logic process element 13 in the logic process zone 111, then the external air gone through the heat exchange is discharged through the first air discharge end. In another embodiment the case body 10 has a first air vent 101 located at one side of the logic process zone 111 remote from the spaced zone 113 and at the first air discharge end of the first airflow 201. When in use, after the first airflow 201 has performed heat exchange with the logic process element 13, it is discharged outside the installation space 11 through the first air vent 101 to form thermal convection to perform cooling for the logic process zone 111. In yet another embodiment, the computer case further includes a third air fan 22 located in the installation space 11 at the first air discharge end of the first air flow 201. The third air fan 22 can be collaborated with the first air fan 20 and set for channeling the external air from the interior of the installation space 11 outside, so that convection of the first airflow 201 is boosted to improve cooling effect of the first airflow 201 to the logic process element 13.

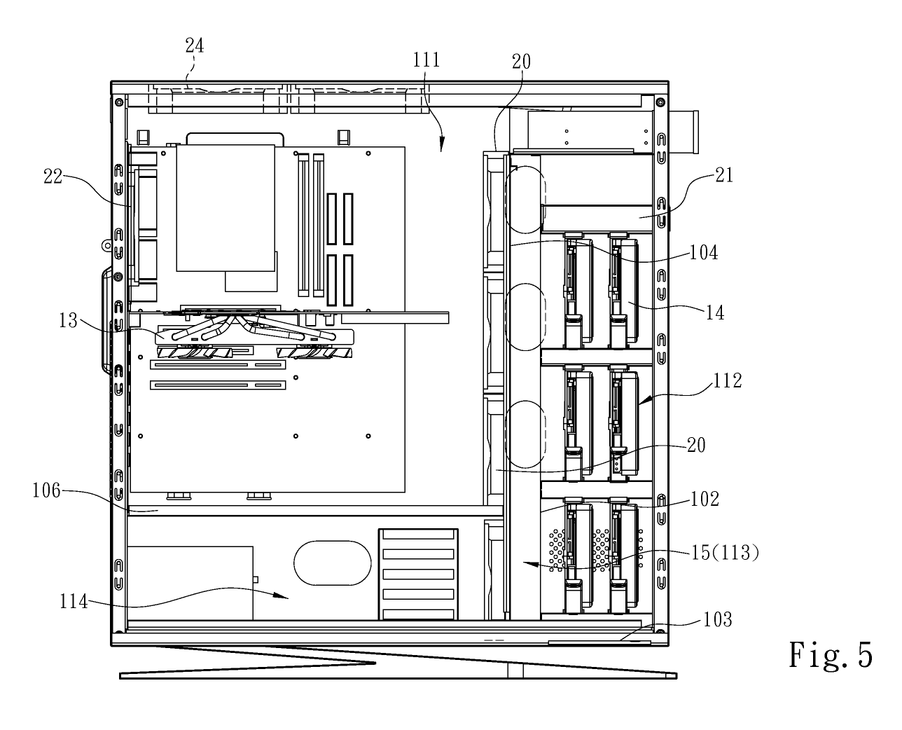

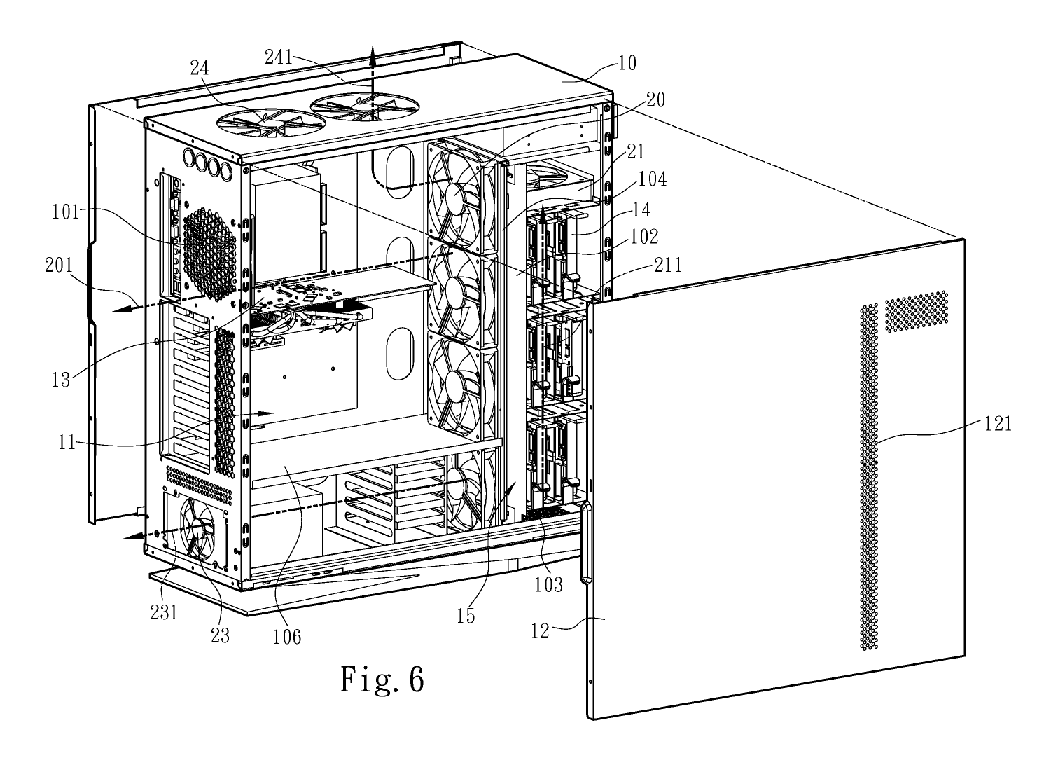

Also referring to FIGS. 2 through 6, the second air fan 21 is located in the installation space 11 at one side of the magnetic disk zone 112, and electrically activated to provide the second airflow 211 to the magnetic disk zone 112. The second airflow 211 and the first airflow 201 do not interfere with each other, as shown in FIG. 6. The second airflow 211 further has a second air intake end and a second air discharge end respectively at two sides of the magnetic disk zone 112. More specifically, the case body 10 includes a first detent wall 102 at one side of the magnetic disk zone 112 abutting the spaced zone 113 to confine the second airflow 211, and the second air vent 103 located at two sides of the magnetic disk zone 112 where the first detent wall 102 is absent and also opposed the second air fan 21 to provide circulation of the external air. In one embodiment the second air fan 21 can be located at the second air discharge end of the second airflow 211, and the second air vent 103 is located at the second air intake end of the second airflow 211, namely, after the second air fan 21 is activated electrically, it draws the air in the magnetic disk zone 112 to generate convection therein and channel the external air inward through the second air vent 103, thus the external air drawn in through the second air vent 103 can perform cooling for the hard disk 14 in the magnetic disk zone 112, then is drawn by the second air fan 21 outside the case body 10. Furthermore, the second air fan 21 can be located at the substantial upper end of the magnetic disk zone 112, and the second air vent 103 can be located at the substantial lower end of the magnetic disk zone 112. Moreover, one side of the magnetic disk zone 112 adjacent to the spaced zone 113 has the first detent wall 102 located thereon to form a closed plane. In another embodiment the second air fan 21 can be located at one side of the magnetic disk zone 112 facing the spaced zone 113 to become the second air intake end of the second airflow 201, and the second air vent 103 can be located at another side of the magnetic disk zone 112 where the second air fan 21 is not installed to become the second air discharge end of the second airflow 211. Thus, one side of the magnetic disk zone 112 faced the spaced zone 113 is an open side. During implementation the second air fan 21 draws the external air through the flow guide passage 15 to enter the magnetic disk zone 112 to perform heat exchange, then the external air gone through the heat exchange is discharged through the second air vent 103. In addition, to confine the external dust from entering the installation space 11, the case body 10 further has the first filter mesh 104 installed on one side of the logic process zone 111 abutting the spaced zone 113 to confine the external dust at the first air intake end of the first airflow 201, or a second filter mesh (not shown in the drawings) at one side of the magnetic disk zone 112 abutting the spaced zone 113 to confine the external dust at the second air intake end of the second airflow 211.

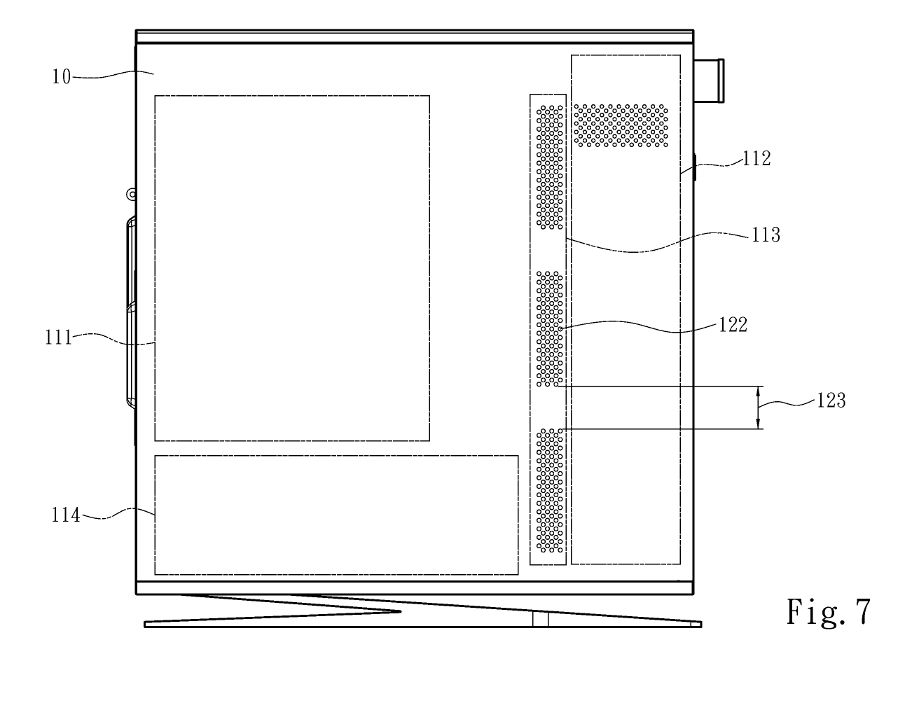

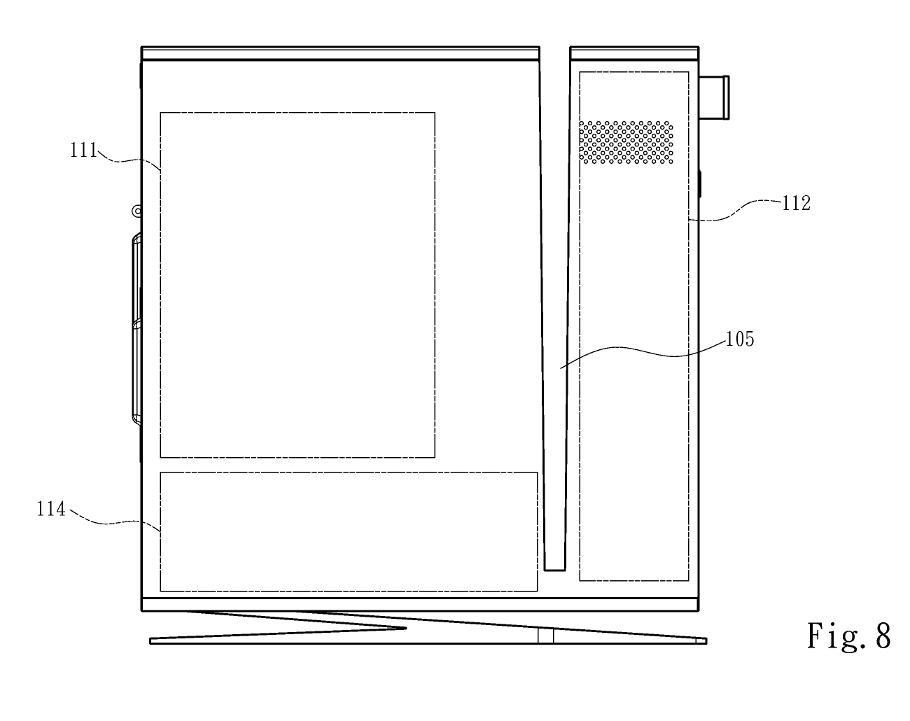

Please referring to FIGS. 1 through 8, each side board 12 of the case body 10 has a flow vent cluster 121 corresponding to the spaced zone 113 and communicating with the installation space 11. Also referring to FIG. 7, in another embodiment each side board 12 has a plurality of flow vent cluster 122 corresponding to the spaced zone 113 and spaced from each other at a preset interval 123, then each flow vent cluster 122 communicates with the installation space 11 to form the flow guide passage 15. In addition, in the aforesaid embodiment, as shown in FIG. 8, the case body 10 can have a longitudinal flow guide channel 105 corresponding to the spaced zone 113 and communicating with the installation space 11 to form the flow guide passage 15.

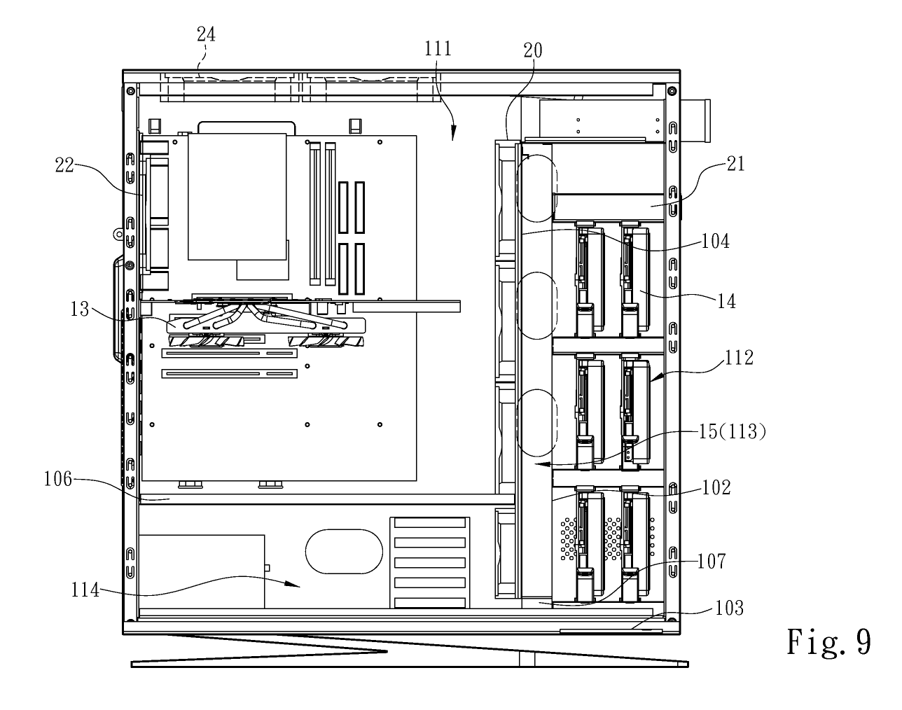

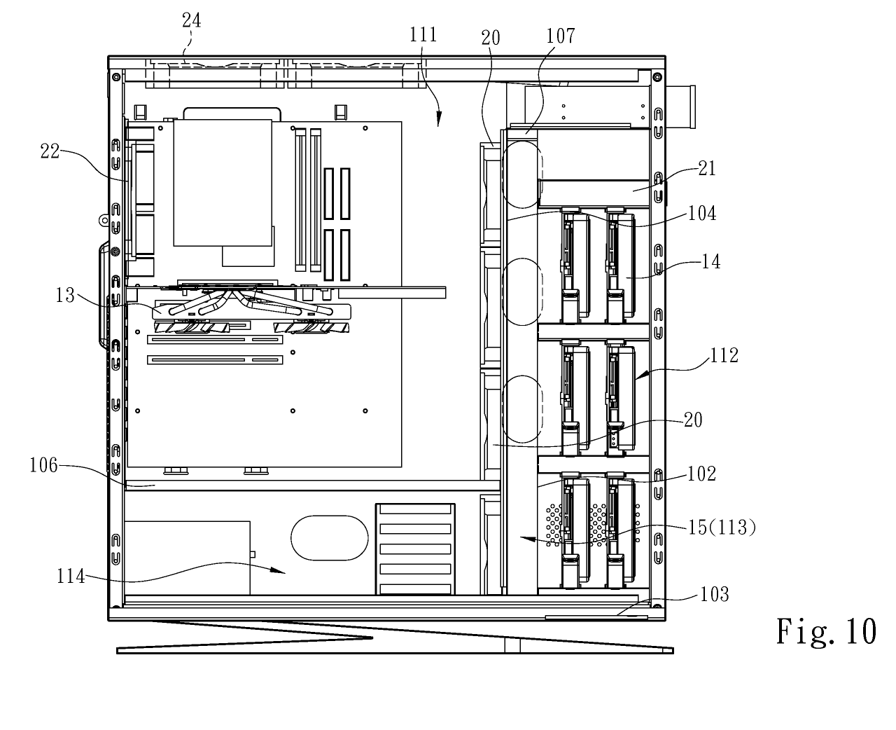

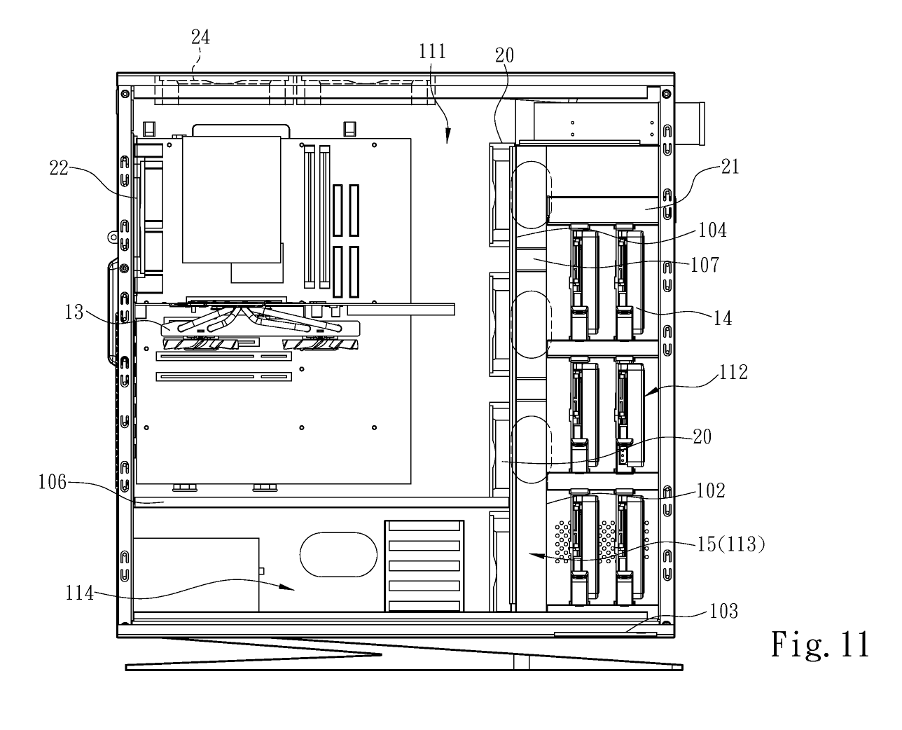

Also referring to FIGS. 2 through 6, in yet another embodiment the installation space 11 has a power supply zone 114 located in the logic process zone 111 without connecting to the spaced zone 113. The computer case has a fourth air fan 23 to receive electric power and provide a third airflow 231 to the power supply zone 114. Furthermore, the fourth air fan 23 can be a power supply air fan which can be set further to channel the air in the installation space 11 outside the case body 10. Thus, the fourth air fan 23 can be collaborated with the first air fan 20 to make the third airflow 231 to provide enhanced cooling effect for the power supply zone 114. Moreover, the case body 10 also can include a second detent wall 106 between the logic process zone 111 and the power supply zone 114 to confine the first airflow 201 and the third airflow 231. In addition, referring to FIGS. 9 through 11, the case body 10 further can have a line passing channel 107 in the spaced zone 113 to communicate with the logic process zone 111 and the magnetic disk zone 112. The line passing channel 107 can include multiple sets according to requirements, as shown in FIG. 11. Furthermore, the line passing channel 107 further can be located in the spaced zone 113 between the substantial top end and the substantial bottom end of the case body 10. In addition, the computer case also can have a top air fan 24 located on the substantial top end of the logic process zone 111 to provide a fourth airflow 241 to the logic process zone 111 upon being activated electrically. In yet another embodiment the fourth airflow can be set to channel the external air drawn by the first air fan 20 into the logic process zone 111 outside the installation space 11.

As a conclusion, the computer case with multiple independent airflows of the invention includes a case body which has an installation space. The installation space includes a logic process zone, a magnetic disk zone and a spaced zone. The case body also has a flow guide passage located in the spaced zone to allow external air to enter the installation space, at least one first air fan located in the installation space and the logic process zone to receive electric power and provide a first airflow to the logic process zone, and a second air fan located in the installation space and the magnetic disk zone to receive electric power and provide a second airflow to the magnetic disk zone. As a result, through the flow guide passage the external air can be directly got to perform cooling for the logic process zone and multiple airflows can be provided to accelerate cooling. Thereby, the invention can provide multiple independent airflows to perform cooling respectively for the logic process zone and the magnetic disk zone, and overcome the problem of the conventional computer cases of performing cooling merely through a single airflow that results in inferior cooling effect.

What is claimed is:

1. A computer case providing multiple independent airflows, comprising:
a case body hollowed to form an installation space which includes a logic process zone, a magnetic disk zone abutting the logic process zone and a spaced zone located between the logic process zone and the magnetic disk zone, and also includes a flow guide passage located in the spaced zone to allow external air to enter the installation space, the flow guide passage including an open side at one side thereof facing the logic process zone and a closed side at another side thereof facing the magnetic disk zone;
at least one first air fan located at one side of the logic process zone to receive electric power to be activated to provide a first airflow to draw the external air from the flow guide passage to enter the logic process zone; and
a second air fan located at one side of the magnetic disk zone to receive electric power to be activated to provide a second airflow to the magnetic disk zone.

2. The computer case of claim 1, wherein the first air fan is located at one side of the logic process zone facing the spaced zone.

3. The computer case of claim 1, wherein the first air fan is located at one side of the logic process zone remote from the spaced zone and at the top surface of the case body.

4. The computer case of claim 1, wherein the first air fan is located at one side of the logic process zone remote from the spaced zone.

5. The computer case of claim 1, wherein the case body includes a first filter mesh located at one side of the logic process zone facing the spaced zone.

6. The computer case of claim 1, wherein the case body includes a second air vent at one side of the magnetic disk zone, and the second air fan is located at another side of the magnetic disk zone opposing the second air vent.

7. The computer case of claim 1, wherein the installation space includes a power supply zone at one side of the logic process zone where the spaced zone is not connected, and the computer case further includes a fourth air fan collaborated with the first air fan to provide a third airflow to the power supply zone.

8. The computer case of claim 7, wherein the fourth air fan is a power supply air fan and the third airflow flows in a direction parallel with the first airflow.

9. The computer case of claim 1, wherein the case body includes a line passing channel located in the spaced zone and communicated with the logic process zone and the magnetic disk zone to hold an electric line.

10. A computer case providing multiple independent airflows, comprising:
a case body hollowed to form an installation space which includes a logic process zone, a magnetic disk zone abutting the logic process zone and a spaced zone located between the logic process zone and the magnetic disk zone, and also includes a flow guide passage located in the spaced zone to allow external air to enter the installation space;
at least one first air fan located in the installation space at one side of the logic process zone abutting the spaced zone to receive electric power to be activated to provide a first airflow to the logic process zone, the first airflow including a first air intake end to draw the external air from the flow guide passage and a first air discharge end at another side of the logic process zone remote from the spaced zone to discharge the external air from the installation space; and
a second air fan located in the installation space at one side of the magnetic disk zone to receive electric power to be activated to provide a second airflow to the magnetic disk zone, the second airflow being not interfering with the first airflow and including a second air intake end and a second air discharge end at two sides of the magnetic disk zone.

11. The computer case of claim 10 further including a third air fan located in the installation space at the first air discharge end of the first airflow.

12. The computer case of claim 10, wherein the second air fan is located at one side of the magnetic disk zone abutting the spaced zone to form the second air intake end of the second airflow, the case body including a second air vent located at another side of the magnetic disk zone where the second air fan is not installed to form the second air discharge end of the second airflow.

13. The computer case of claim 10 further including two side boards installed respectively at two sides of the case body to seal the installation space after installation, each side board including a flow vent cluster corresponding to the spaced zone and communicating with the installation space to form the flow guide passage.

14. The computer case of claim 10, wherein the case body includes a longitudinal flow guide channel corresponding to the spaced zone and communicating with the installation space to form the flow guide passage.

15. The computer case of claim 10, wherein the case body includes a first filter mesh located at one side of the logic process zone abutting the spaced zone to confine external dust at the first air intake end of the first airflow.

16. The computer case of claim 10, wherein the installation space includes a power supply zone located at one side of the logic process zone where the spaced zone is not connected, and the computer case further includes a fourth air fan activated electrically to provide a third airflow to the power supply zone.

17. The computer case of claim 16, wherein the case body includes a second detent wall located between the logic process zone and the power supply zone to confine the first airflow and the third airflow.

18. The computer case of claim 10 further including a top air fan located on a substantial top end of the logic process zone to be electrically activated to provide a fourth airflow to the logic process zone.

19. The computer case of claim 10, wherein the case body includes a line passing channel located in the spaced zone and communicated with the logic process zone and the power supply zone to hold an electric line.

20. The computer case of claim 10, wherein the line passing channel is located in the spaced zone between a substantial top end and a substantial bottom end of the case body.
